(19) United States
(12) Patent Application Publication
(10) Pub. No.: US 2026/0066906 A1
(43) Pub. Date: Mar. 5, 2026

(54) PHASE-LOCKED LOOP WITH MONITORED DIGITAL-TO-TIME CONVERTER

(71) Applicant: Robert Bosch GmbH, Stuttgart (DE)

(72) Inventors: Michael Wickert, Dresden (DE); Reiner Schnitzer, Reutlingen (DE)

(21) Appl. No.: 19/307,351

(22) Filed: Aug. 22, 2025

(30) Foreign Application Priority Data
Sep. 2, 2024 (DE) 10 2024 208 293.7

(51) Int. Cl. H03L 7/091; G04F 10/00; H03K 19/20; H03L 7/099

(52) U.S. Cl. CPC H03L 7/091; G04F 10/005; H03L 7/0995; H03K 19/20

(57) ABSTRACT

A phase-locked loop. The phase-locked loop including a time-to-digital converter for acquiring a phase of a reference signal. A feedback signal formed from an output signal of the phase-locked loop is fed to the time-to-digital converter. The phase-locked loop including a digital-to-time converter which is configured to apply dithering to the feedback signal or to the reference signal. The digital-to-time converter is part of a ring oscillator with a predefined oscillation frequency. The phase-locked loop includes an evaluation unit for acquiring an actual frequency of the ring oscillator.

### FIELD

The present invention relates to a phase-locked loop. The phase-locked loop is supported by a digital-to-time converter and allows monitoring of the performance of the digital-to-time converter.

### BACKGROUND INFORMATION

In phase-locked loops, it is common practice to provide support in the form of a digital-to-time converter. This means that dithering is applied to a feedback signal or the reference signal of the phase-locked loop. Safety requirements may necessitate monitoring the digital-to-time converter within the framework of a self-test. Such monitoring can be very difficult, however; in particular in highly complex digital phase-locked loops with digital-to-time converters. Direct measurement of the digital-to-time converter with a range of less than 100 ps and a maximum step size of 1 ps with an accuracy of <0.3 LSB, for instance, is difficult to achieve on a system-on-a-chip.

### SUMMARY

The phase-locked loop according to the present invention makes it possible to reliably acquire the performance of a digital-to-time converter being used in it within the framework of a self-test and thus reliably ascertain a state of health of the digital-to-time converter. This ascertainment can in particular be carried out reliably and in a time-efficient manner. The phase-locked loop thus permits a reliable self-test, also known as a built-in self-test (BIST).

According to an example embodiment of the present invention, the phase-locked loop comprises a time-to-digital converter for acquiring a phase of a reference signal. The phase-locked loop is formed by feeding a feedback signal formed from an output signal of the phase-locked loop back to the time-to-digital converter.

The phase-locked loop also comprises a digital-to-time converter, which is configured to apply dithering to the feedback signal or to the reference signal. In particular in digital phase-locked loops, the digital-to-time converter is used to apply dithering to the relatively coarse quantization steps of the phase measurement using a time-to-digital converter of the phase-locked loop. In order to suppress or avoid aliasing effects, the time steps of the digital-to-time converter are typically selected such that they are significantly smaller than those of the time-to-digital converter. These short time steps make monitoring by means of time measurement or conversion into voltages or currents more difficult when monitoring is to be carried out with high precision requirements.

It is therefore provided that the digital-to-time converter is part of a ring oscillator with a predefined oscillation frequency. Because a predefined delay of the digital-to-time converter is expected for each input value, the predefined oscillation frequency is in particular dependent on an input value of the digital-to-time converter and this delay is reflected in the predefined oscillation frequency. A frequency can also be measured with high precision and easily generated by the ring oscillator, so that the frequency is an optimal criterion for ascertaining a state of health of the digital-to-time converter being used.

The phase-locked loop comprises an evaluation unit for acquiring an actual frequency of the ring oscillator. This provides the actual frequency of the ring oscillator, which can be ascertained easily and with high precision. It also provides a target frequency, which enables a comparison. This makes it possible to reliably ascertain a state of health of the digital-to-time converter.

Preferred further developments of the present invention are disclosed herein.

According to an example embodiment of the present invention, the ring oscillator preferably comprises a delay element with a fixed delay. The delay element makes it possible to set the predefined oscillation frequency of the ring oscillator to the framework conditions of the evaluation unit. The delay element also makes it possible to minimize negative influences of the ring oscillator on the digital-to-time converter. The delay element can in particular be adjusted to calibrate the delay; for example to adapt the delay to process variations during manufacture of the phase-locked loop or the hardware of the phase-locked loop.

A NAND module is particularly preferably disposed between the delay element and an output of the digital-to-time converter. This module comprises the output of the digital-to-time converter and a test execution signal as inputs. If a test is to be carried out, the output of the digital-to-time converter is fed to the delay element and in particular back to the input of the digital-to-time converter in order to form a ring needed for the ring oscillator.

According to an example embodiment of the present invention, a multiplexer is preferably connected upstream of a reference clock input of the digital-to-time converter. The multiplexer is configured to apply either a reference clock signal or the output of the delay element to the reference clock input as a function of the test execution signal. This again forms a ring when a test is to be carried out. Outside of times when tests are to be carried out, normal function of the digital-to-time converter without influence from the ring oscillator is achieved.

According to an example embodiment of the present invention, the evaluation unit preferably comprises a counter. The counter is used to count the oscillation periods of the ring oscillator. This makes it possible to ascertain the actual frequency of the ring oscillator. Counting the oscillation periods is simple and can be done with high precision. It is thus possible to acquire high-quality measurement results that can be used to determine the state of health of the digital-to-time converter.

The counter is preferably a binary counter with the size N. N is a natural number. The counter is particularly advantageously implemented digitally.

According to an example embodiment of the present invention, it is furthermore preferably provided that the evaluation unit comprises a sampling module. The sampling module serves to sample an output of the counter with a predefined clock signal. Thus frequency can be determined because sampling combines a time factor with the result of the counter, so that the number of oscillation periods per unit of time can be ascertained. This makes it possible to ascertain the actual oscillation frequency of the ring oscillator.

According to an example embodiment of the present invention, the evaluation unit particularly advantageously comprises a frequency estimation module. The frequency estimation module is configured to efficiently estimate the actual frequency of the ring oscillator based on the output of the sampling module. Thus enables an in particular ongoing and reliable ascertainment of the actual frequency of the ring oscillator.

According to an example embodiment of the present invention, the frequency estimation module is in particular configured to estimate the actual frequency of the ring oscillator using the least squares method. This in particular enables a rapid ascertainment of the frequency; i.e. reliable ascertainment of the frequency based on a few oscillation periods of the ring oscillator, even in the presence of unavoidable noise The ascertained actual frequencies can be analyzed in a further step and used to identify inconsistencies in the operation of the digital-to-time converter and thus obtain a state of health of the digital-to-time converter.

In an advantageous embodiment of the present invention, the evaluation unit is configured to estimate an integral nonlinearity and/or a differential nonlinearity of the digital-to-time converter by comparing the actual frequency with the predefined oscillation frequency.

### BRIEF DESCRIPTION OF THE DRAWINGS

Embodiment examples of the present invention are described in detail in the following with reference to the figures.

FIG. 1A shows a schematic view of a phase-locked loop according to an embodiment example of the present invention when using the digital-to-time converter in the feedback path.

FIG. 1B shows a schematic view of a phase-locked loop according to an embodiment example of the present invention when using the digital-to-time converter in the path of the reference signal.

FIG. 2 shows a schematic view of a ring oscillator with a digital-to-time converter of the phase-locked loop according to the embodiment example of the present invention.

### DETAILED DESCRIPTION OF EXAMPLE EMBODIMENTS

All same components, elements, and/or units are preferably provided with the same reference signs in all of the figures.

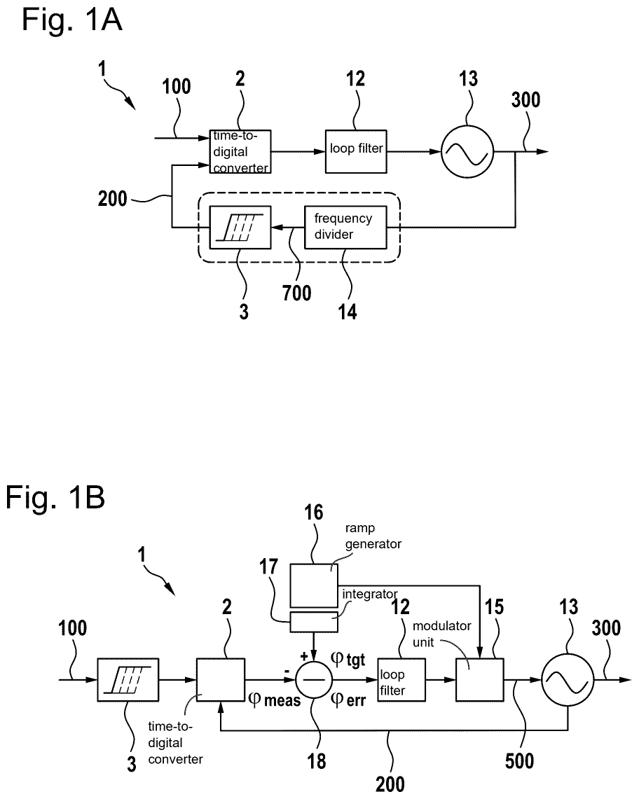

FIG. 1A schematically shows a phase-locked loop (PLL) 1. The phase-locked loop 1 is in particular a digital phase-locked loop (DPLL) or a fully digital phase-locked loop, also referred to as an all digital phase-locked loop (ADPLL). The phase-locked loop 1a is supported by a digital-to-time converter 3 in the feedback path.

The phase-locked loop 1 is used to track a phase of an oscillator in accordance with the phase of a reference signal 100. In the shown embodiment example, a digitally controlled oscillator (DCO) 13 is provided. To ascertain the phase, the reference signal 100 is first fed to a time-to-digital converter 2, in which case the result passes through a loop filter 12 and reaches the oscillator 13. The loop filter 12 is a digital loop filter (DLF), for instance. The resulting output signal 300 is fed back to obtain a feedback signal 200 and the feedback signal 200, too, is fed to the time-to-digital converter 2.

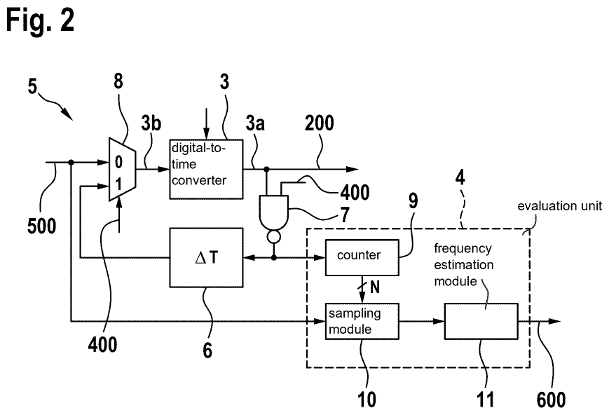

The feedback signal 200 passes through a frequency divider 14, for example, and an output 700 of the frequency divider 14 is fed to the digital-to-time converter 3 in order to apply dithering to the feedback signal 200. The digital-to-time converter 3 has a step size of 1 ps, with a range of 63 ps for instance. It is therefore not easy to acquire the performance of the digital-to-time converter 3. To nonetheless enable a self-test, the digital-to-time converter 3 is embedded in a ring oscillator 5 which is illustrated schematically in FIG. 2. This makes it possible to enable a built-in self-test, abbreviated to BIST.

FIG. 1B shows an alternative implementation of the phase-locked loop 1, wherein the phase-locked loop 1 here comprises a phase ascertainment unit 2, 3 which is configured to acquire a phase difference between a reference signal 100 and a feedback signal 200 and to output a measurement signal φₘₑₐₛ representing the phase difference.

The phase ascertainment unit 2, 3 comprises a series circuit consisting of the digital-to-time converter 3 and a time-to-digital converter 2 for phase measurement. The digital-to-time converter 3 is connected upstream of the time-to-digital converter 2 and serves to apply a dither to the reference signal 100 which can be fed to the digital-to-time converter 3. An output of the digital-to-time converter 3 can be fed to the time-to-digital converter 2, wherein the applied dithering is advantageous for taking into account the relatively coarse quantization steps of the time-to-digital converter 2. The feedback signal 200 can also be fed to the time-to-digital converter 2.

In this embodiment example, the phase-locked loop 1 further comprises an optional modulator unit 15, wherein the modulation in the shown embodiment example is a two-point modulation. An optional specification unit 16, 17 which is configured to generate a target signal φ_{tgt} is provided for this purpose. In the shown embodiment example, the specification unit 16, 17 comprises a ramp generator 16 which serves to generate a ramp signal. This ramp signal is converted to the target signal φ_{tgt} via an integrator 17. The ramp signal is in particular also output to the modulator unit 15.

A phase deviation ascertainment unit 18 is configured to generate an error signal φₑᵣᵣ from the measurement signal φₘₑₐₛ and the target signal φ_{tgt}. The aforementioned two-point modulation is achieved by taking the target signal φ_{tgt} into account.

The phase-locked loop 1 comprises a loop filter 12 for filtering the error signalφₑᵣᵣ, wherein the output of the loop filter 12 can be fed to the modulator unit 15. The loop filter 12 is a digital loop filter (DLF), for instance. The modulated or, in an alternative embodiment, the unmodulated result of the time-to-digital converter 2 is thus output to the loop filter 12.

The modulator unit 15 serves to modulate the filtered error signal and generate a tune signal 500. The tune signal 500 can be used to control the oscillator 13, wherein the oscillator 13 is configured to generate an output signal 300 from the tune signal 500. The feedback signal 200 fed to the phase ascertainment unit 2 is formed from the output signal 300 of the phase-locked loop 1.

The modulator unit 15 represents a second point of the two-point modulation. The modulator unit 15 is a delta-sigma modulator, for example. If modulation is not desired, in an alternative embodiment, the modulator unit 15 and the specification unit 16, 17 as well as the phase deviation ascertainment unit 18 can be omitted.

FIG. 2 schematically shows a ring oscillator 5 of the phase-locked loop 1 according to the embodiment example of the present invention. The digital-to-time converter 3 is part of this ring oscillator 5, wherein the ring oscillator has a predefined oscillation frequency. The predefined oscillation frequency is influenced by the digital-to-time converter 3, because said digital-to-time converter causes a corresponding delay for a predetermined input value which leads to the predefined oscillation frequency. The oscillation frequency of the ring oscillator 5 thus represents a measure of the functionality of the digital-to-time converter 3. Comparing the predefined oscillation frequency with an acquired actual frequency of the ring oscillator 5 thus makes it possible to ascertain a state of health of the digital-to-time converter 3. The phase-locked loop 1 therefore comprises an evaluation unit 4 for acquiring an actual frequency of the ring oscillator 5.

A NAND module 7 is provided, which comprises the output 3a of the digital-to-time converter 3 and a test execution signal 400 as inputs. The output of the NAND module 7 is fed to a delay element 6 with a fixed delay. A multiplexer 8 is preferably connected upstream of a reference clock input 3b of the digital-to-time converter 3. The multiplexer 8 is configured to apply either a reference clock signal 500 or the output of the delay element 6 to the reference clock input 3b as a function of the test execution signal 400. The ring oscillator 5 can thus be used to close the test execution signal 400 in order to test the digital-to-time converter 3.

The evaluation unit 4 comprises a counter 9 for counting the oscillation periods of the ring oscillator 5. The counter 9 is a binary counter with the size N, wherein N is a natural number. The evaluation unit 4 also comprises a sampling module 10 for sampling an output of the counter 9 with a predefined clock signal. The predefined clock signal is the reference clock signal 500.

The evaluation unit 4 further comprises a frequency estimation module 11. The frequency estimation module 11 is configured to estimate the actual frequency of the ring oscillator 5 based on the output of the sampling module 10. In this embodiment example, this is done using the least squares method.

The described design makes it possible to ascertain a state of health of the digital-to-time converter using the actual frequency of the ring oscillator 5. The actual frequency is reliably acquired by the frequency estimation module 11, and requires only a few oscillation periods of the ring oscillator 5. The fixed delay of the delay element 6 allows the oscillation frequency of the ring oscillator 5 to be adapted to the properties and boundary conditions of the counter 9 and the sampling module 10. It is moreover also possible to eliminate production-related variations via calibration.

The fixed delay 6 is 200 ps, for example. With an example step size of the digital-to-time converter 3 of 1 ps and 64 steps [0 . . . 63], this results in a frequency of the ring oscillator 5 of [1.901; 1.908; . . . 2.487; 2.5] GHz, for instance. In this case, the smallest frequency step is 7.25 MHz, because, for one period of the ring oscillator 5, the delay element 6 and the digital-to-time converter 3 are passed through twice.

With a reference clock signal 500 of 100 MHz, the necessary size N of the counter 9 can be calculated using the formula:

$$N = ceil ( {log}_{2} ( \frac{2.5 GHz}{100 MHz} ) ) = 5 bit$$

The operation ceil ( . . . ) rounds up to the next natural number. Consequently, a 5 bit counter 9 is used to count the oscillation periods of the ring oscillator 5 in order to reliably ascertain the actual frequency of the ring oscillator 5.

The required measurement accuracy is 1/10 LSB, for example. This means a standard deviation of <725 kHz. Based on linear regression, this then results in a specification of 27 samples of the counter 9. A total duration of a test cycle with 64 steps of the digital-to-time converter 3 can thus be calculated using the formula:

$${T}_{BIST} = \frac{1}{100 MHz} \times 64 \times 27 = 17.28 μs$$

A test of the digital-to-time converter 3 can thus be carried out in a very short time with a high degree of accuracy by ascertaining the actual frequency of the ring oscillator 5. The evaluation unit 4 is configured to estimate an integral nonlinearity and/or a differential nonlinearity of the digital-to-time converter 3, for instance, by comparing the actual frequency with the predefined oscillation frequency. This provides the possibility of a reliable self-test.

1-10. (canceled)

11. A phase-locked loop, comprising:
a time-to-digital converter configured to acquire a phase of a reference signal, wherein a feedback signal formed from an output signal of the phase-locked loop is fed to the time-to-digital converter;
a digital-to-time converter configured to apply dithering to the feedback signal or to the reference signal, wherein the digital-to-time converter is part of a ring oscillator with a predefined oscillation frequency; and
an evaluation unit configured to acquire an actual frequency of the ring oscillator.

12. The phase-locked loop according to claim 11, wherein the ring oscillator includes a delay element with a fixed delay.

13. The phase-locked loop according to claim 12, wherein a NAND module, which includes an output of the digital-to-time converter and a test execution signal as inputs, is disposed between the delay element and the output of the digital-to-time converter.

14. The phase-locked loop according to claim 13, wherein a multiplexer is connected upstream of a reference clock input of the digital-to-time converter, wherein the multiplexer is configured to apply either a reference clock signal or an output of the delay element, to the reference clock input as a function of the test execution signal.

15. The phase-locked loop according to claim 11, wherein the evaluation unit includes a counter configured to count oscillation periods of the ring oscillator to ascertain an actual frequency of the ring oscillator.

16. The phase-locked loop according to claim 15, wherein the counter is a binary counter with a size N, wherein N is a natural number.

17. The phase-locked loop according to claim 15, wherein the evaluation unit includes a sampling module configured to sample an output of the counter with a predefined clock signal.

18. The phase-locked loop according to claim 17, wherein the evaluation unit includes a frequency estimation module which is configured to estimate the actual frequency of the ring oscillator based on an output of the sampling module.

19. The phase-locked loop according to claim 18, wherein the frequency estimation module is configured to estimate the actual frequency of the ring oscillator using a least-squares fitting method.

20. The phase-locked loop according to claim 15, wherein the evaluation unit is configured to estimate an integral nonlinearity and/or a differential nonlinearity of the digital-to-time converter, by comparing the actual frequency with the predefined oscillation frequency.
